(19) United States
(12) Patent Application Publication
(10) Pub. No.: US 2026/0237431 A1
(43) Pub. Date: Aug. 13, 2026

(54) IN-MEMORY ACCELERATION USING 6T-RRAMS WITH SIGNED WEIGHT VALUES

(71) Applicant: Government of the United States as represented by the Secretary of the Air Force, Wright-Patterson AFB, OH (US)

(72) Inventors: Kang Jun Bai, New Hartford, NY (US); Hao Jiang, San Jose, CA (US)

(21) Appl. No.: 19/460,918

(22) Filed: Jan. 27, 2026

Related U.S. Application Data
(60) Provisional application No. 63/758,001, filed on Feb. 13, 2025.

(51) Int. Cl. G11C 13/00; G11C 11/54

(52) U.S. Cl. CPC G11C 13/004; G11C 11/54; G11C 13/0007; G11C 2213/32

(57) ABSTRACT

A memristive circuit includes a signal source; a bit line; and a six-transistor, one-resistive random-access memory (6T1R) cell. The RRAM element is configured to store a plurality of resistance states corresponding to magnitudes of synaptic weights, a sign and magnitude of the synaptic weight being determined by a direction and a magnitude of current conducted through the RRAM element via one of the positive-weight conduction loop and the negative-weight conduction loop; and during a read operation, the resistance state of the RRAM element modulates a current on the bit line, a magnitude of the current thereby representing the magnitude of the synaptic weight.

### RIGHTS OF THE GOVERNMENT

The invention described herein may be manufactured and used by or for the Government of the United States for all governmental purposes without the payment of any royalty.

Pursuant to 37 C.F.R. § 1.78(a)(4), this application claims the benefit of and priority to prior filed co-pending Provisional Application Ser. No. 63/758,001, filed Feb. 13, 2025, which is expressly incorporated herein by reference in its entirety.

### FIELD OF THE INVENTION

The present invention relates generally to compute-in-memory devices and, more particularly, to compute-in-memory devices having multiple transistors and one resistive random access memory.

### BACKGROUND OF THE INVENTION

Traditional machine-learning hardware separates memory and computation into distinct physical blocks (e.g., “von Neumann architectures”). Neural-network weights may be stored in conventional memory arrays while multiply-accumulate operations are executed in separate digital logic units. This separation forces data to shuttle repeatedly between memory and processor, introducing potential errors and inefficiencies (e.g., “memory wall bottleneck,” etc.) As neural networks increase in size and complexity, the energy and latency associated with weight fetching dominate total system cost. Further, multi-bit weight storage often requires two or more memory cells per synapse, and storing positive and negative values normally requires paired devices or elaborate digital encoding schemes. These constraints have made it increasingly difficult to scale deep-learning systems in an energy-efficient manner, particularly in edge-computing environments with tight area and power budgets.

Compute-in-memory (CIM) architectures attempt to alleviate these challenges by performing at least part of the computation within the memory array itself. Resistive-RAM (RRAM) devices are especially attractive for CIM because their analog conductance states naturally support multiply-accumulate operations. However, existing RRAM CIM designs have struggled to provide compact support for signed (+/−) weights, requiring two 1T1R devices per synapse (one positive, one negative) or additional digital circuitry that increases area and degrades array efficiency. Accordingly, there may be a need for improved RRAM-based CIM cells.

### SUMMARY OF THE INVENTION

The present invention overcomes the foregoing problems and other shortcomings, drawbacks, and challenges of current electronic circuits for assigning synaptic weights. While the invention will be described in connection with certain embodiments, it will be understood that the invention is not limited to these embodiments. To the contrary, this invention includes all alternatives, modifications, and equivalents as may be included within the spirit and scope of the present invention.

According to one embodiment of the present invention a memristive circuit includes a signal source; a bit line; and a six-transistor, one-resistive random-access memory (6T1R) cell including: a resistive random-access memory (RRAM) element having a first terminal and a second terminal, the second terminal being electrically coupled to the bit line; a positive-weight conduction loop including: a first transistor (M₁) having a gate configured to receive a positive-state gate voltage (Vₚ), a source coupled to the signal source, and a drain configured to control a state of a logic inverter, the first transistor is configured to selectively pass the signal source to the logic inverter; the logic inverter, comprising a third transistor (M₃) and a fourth transistor (M₄), each having gates coupled to the drain of M₁, the logic inverter having an output; and a fifth transistor (M₅) having a gate coupled to the output of the logic inverter, a source coupled to a training supply voltage (VDD), and a drain coupled to the first terminal of the RRAM element; and a negative-weight conduction loop including a second transistor (M₂) having a source coupled to the signal source and a gate configured to receive a negative-state gate voltage (Vₙ); and a sixth transistor (M₆) having a gate coupled to a drain of the second transistor, a drain coupled to the first terminal of the RRAM element, and a source coupled to ground. The RRAM element is configured to store a plurality of resistance states corresponding to magnitudes of synaptic weights, a sign and magnitude of the synaptic weight being determined by a direction and a magnitude of current conducted through the RRAM element via one of the positive-weight conduction loop and the negative-weight conduction loop; and during a read operation, the resistance state of the RRAM element modulates a current on the bit line, a magnitude of the current thereby representing the magnitude of the synaptic weight.

According to another embodiment of the present disclosure, an array of memristive circuit cells includes: a word line; a bit line; a plurality of a six-transistor, one-resistive random-access memory (6T1R) cells coupled between the word line and bit line, each cell including a resistive random-access memory (RRAM) element having a first terminal and a second terminal, the second terminal being electrically coupled to the bit line; a positive-weight conduction loop including: a first transistor (M₁) having a gate configured to receive a positive-state gate voltage (Vₚ), a source coupled to the word line, and a drain configured to control a state of a logic inverter, the first transistor is configured to selectively pass the signal source to the logic inverter; the logic inverter, comprising a third transistor (M₃) and a fourth transistor (M₄), each having gates coupled to the drain of M₁, the logic inverter having an output; and a fifth transistor (M₅) having a gate coupled to the output of the logic inverter, a source coupled to a training supply voltage (VDD), and a drain coupled to the first terminal of the RRAM element; and a negative-weight conduction loop including a second transistor (M₂) having a source coupled to the word line and a gate configured to receive a negative-state gate voltage (Vₙ); and a sixth transistor (M₆) having a gate coupled to a drain of the second transistor, a drain coupled to the first terminal of the RRAM element, and a source coupled to ground; and each RRAM element is configured to store a plurality of resistance states corresponding to magnitudes of synaptic weights, a sign and magnitude of the synaptic weight being determined by a direction and a magnitude of current conducted through the RRAM element via one of the positive-weight conduction loop and the negative-weight conduction loop, asserting a voltage on the word line selects each cell coupled thereto by providing an input voltage to the source of the first transistor (M₁) and the source of the second transistor (M₂), thereby enabling one of the positive-weight conduction loop and the negative-weight conduction loop to modify the resistance state of the RRAM element, and during a read operation, the resistance state of the RRAM element modulates a current on the bit line, a magnitude of the current thereby representing the magnitude of the synaptic weight.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1A shows a schematic of a resistive random-access memory (RRAM) consisting of a top electrode, a bottom electrode, and a conductive filament, according to one or more embodiments shown and described herein.

FIG. 1B shows another state of the RRAM of FIG. 1A.

FIG. 2A shows an embodiment of an RRAM according to one or more of the embodiments shown and described herein.

FIG. 2B shows additional details of the RRAM of FIG. 2A.

FIG. 3 shows a wafer piece for device characterization according to one or more of the principles described herein.

FIG. 4A, FIG. 4B, and FIG. 4C show device characteristics of HfO₂ RRAM.

FIG. 5A and FIG. 5B show a cell configuration and operating principle for an AND gate.

FIG. 5C and FIG. 5D show the cell configuration and operating principle for an OR gate.

FIG. 5E and FIG. 5F show the cell configuration and operating principle for an XOR gate.

FIG. 6A, FIG. 6B, and FIG. 6C show various characteristics of a 4×6 crossbar array according to one or more embodiments shown and described herein.

FIG. 7 shows a training mode cell configuration for a 6T1R cell and operating principle of the 6T1R under a training mode to increase an RRAM's resistance.

FIG. 8 shows a cell configuration and operating principle of the 6T1R under the training mode to reduce RRAM's resistance.

FIG. 9 shows a cell configuration and operating principle of the 6T1R under the inference mode with positive weight values.

FIG. 10 shows a cell configuration and operating principle of the 6T1R under the inference mode with negative weight values.

FIG. 11A, FIG. 111B, and FIG. 11C show the switching behaviors of 6T1R cell during the SET operation from LRS to HRS, the RESET operation from HRS to LRS, and the number of required pulsing periods with respect to the duty cycle of PWM pulses, respectively.

FIG. 12 shows a layout of a single-layer perceptron (SLP) classifier built on a 4×2 memristive crossbar array with 6T1R configuration.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

As alluded to above, there exists a need for new compute-in-memory architecture. Compute-in-memory (CIM) architectures attempt to alleviate the challenges of traditional architectures by performing at least part of the computation within the memory array itself. The analog conductance states resistive-RAM (RRAM) devices are especially attractive for CIM because they naturally support multiply-accumulate operations. But the current 1T1R architectures can require additional digital circuitry that increases area and degrades array efficiency. The systems and methods described herein may increase computational efficiency based on several factors. For instance, they (i) use fewer devices per synapse, (ii) support robust, bidirectional current steering for positive and negative weight representation, and (iii) reduce overall array footprint, while maintaining compatibility with standard CMOS fabrication flows. The present disclosure addresses these and other needs by introducing a six-transistor-one-RRAM (6T1R) memristive computing cell that enables bidirectional current conduction through a single RRAM element, allowing a single device to store weight magnitude while transistor-controlled current direction encodes sign. This structure reduces area, improves energy efficiency, and supports high-performance in-memory neural-network computation. These increases in efficiency and performance may be required because the need for artificial intelligence (AI) and machine learning (ML) systems is increasing.

From screening tests for types of cancer to searching for exoplanets, today's AI and ML algorithms have given rise to great improvements in a broad spectrum of modern society. Alongside the AI/ML development, neuromorphic computing with methods based on CIM is one class of the next-generation computing architectures. Beside alleviating costs in latency and energy associated with data movement between processing and memory units, neuromorphic computing also has potential to reduce the computational complexity associated with data-intensive applications. This arises mostly from the massive parallelism afforded by millions of computational memory cells deployed in dense arrays.

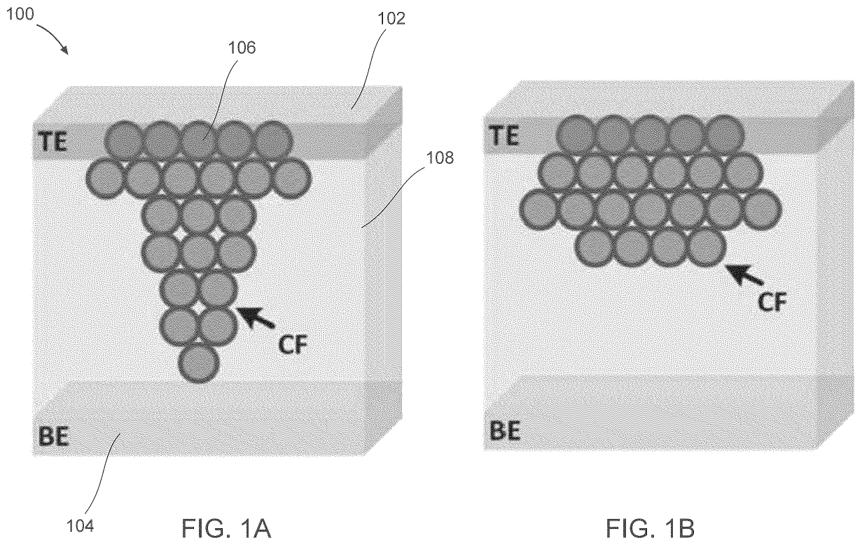

Computational memory is the basic building block to an in-memory operator, satisfying the demands of scalability, reliability, and efficiency needed to justify computation at scale. Specifically, RRAM is an emerging class of computational memory where information can be stored and computed concurrently. As shown in FIG. 1A and FIG. 1, RRAM 100 consists of a top electrode (TE) 102, a bottom electrode (BE) 104, and a conductive filament (CF) 106 between the TE 102 and BE 104. The RRAM is in a metal-oxide-metal structure with the formation of CFs in the oxide material 108. Such CF, which are formed and dissolved by voltage pulses, change the overall resistance of the device between its high resistance state (HRS) (FIG. 1B) and low resistance state (LRS) (FIG. 1A). The processes that control the CF can be used to control the amount of current written into the device. The nonvolatile accumulative behavior enables RRAM to store a continuum of resistance values and facilitate the key computational primitive of analogue multiply-and-accumulate (MAC) operations, with methods based on fundamental laws, such as Ohm's law and Kirchhoff's current law.

As a type of memristor, RRAM also demonstrates the non-volatility, a large on/off ratio (greater than 10), a high switching speed (below 100 ns), a high cycling endurance (more than 10 billion cycles), and a high memory density that is supported by the three-dimensional (3D) stacking, large on/off ratio (greater than 10), and ability of supporting multi-bit computation per single cell.

Along with the inherent nonlinear and stochastic nature, RRAM can be exploited in accelerating and training AI/ML algorithms for a wide range of application domains. Specifically, CIM merges computation directly into memory sub-arrays, reducing the computational complexity of a problem as well as the amount of data being accessed from memory units. Building upon this effective architecture, scientific computing for calculating linear algebra kernels with analogue MAC operations can be accelerated by the high parallelism from the crossbar array and the multi-bit computation ability from RRAM, better yet, improving the memory density required for data storage. Likewise, signal processing for approximating solutions (e.g., computer vision related problems) and associative memory can be exploited to perform certain ML tasks. Beyond that, deep neural networks (DNNs) can be mapped onto multiple crossbar arrays of RRAMs interconnected with each other, where each layer performs a single step and directly feeds to the next, accelerating neural-inspired computations to extreme efficiency. Last but not least, stochastic computing leverages the stochasticity associated with the switching behavior in RRAM for data encryption, opening new opportunities for application security.

Designing and applying memristive circuitry for AI/ML related workloads are described herein. Major topics of this specification can be summarized as follows: an in-depth characteristic analysis of hafnium-oxide RRAM with respect to various circuit configurations and switching conditions; a demonstration of flow-based Boolean arithmetic using 1-transistor-1-RRAM (1T1R) crossbar array; a prototype of single-layer perceptron (SLP) classifier for dark pixel positioning; and an in-situ training with enhanced 6-transistor-1-RRAM (6T1R) crossbar array alongside a proof-of-concept demonstration for a classification problem.

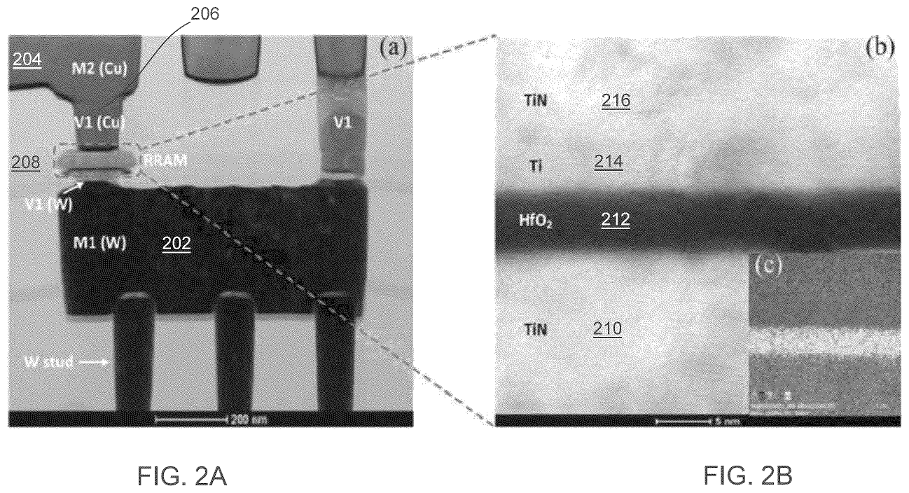

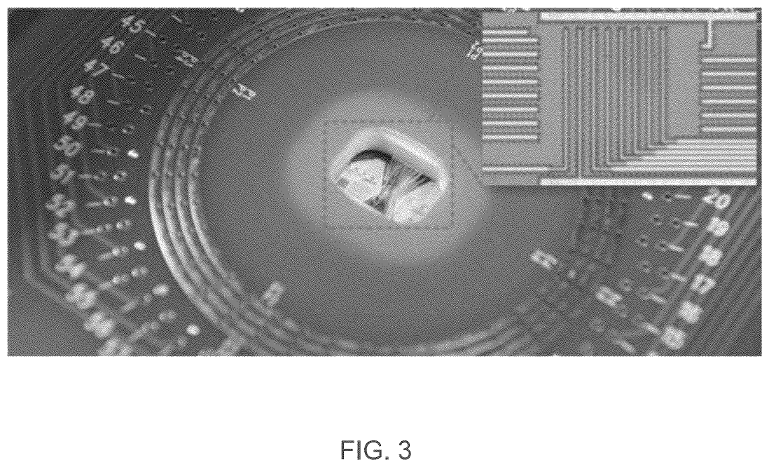

A hafnium-oxide (HfO₂) RRAM can be designed and fabricated, for instance, using a custom 65 nm CMOS/RRAM technology node in a 300 mm foundry. In some embodiments, the device can be implemented through a front-end-of-the-line (FEOL) compatible process and stacked between different metal layers. As shown in FIG. 2A, the layers can include a metal-1 (M₁) 202 and metal-2 (M2) 204 layer. An intervening via-1 (V1) 206 layer can be split to create the RRAM component 208 with its CF in the oxide layer. FIG. 2A shows a transmission electron microscopy (TEM) and FIG. 2B shows an energy dispersive X-ray spectroscopy (EDS) map of one embodiment of the RRAM described herein. The cross-sectional contrast micrograph of FIG. 2B shows Nitrogen (N) in green, oxygen (O) in blue, silicon (Si) in cyan, titanium (Ti) in purple, and hafnium (Hf) in yellow. Embodiments of the RRAM can include, for example, a titanium-nitride (TiN) bottom electrode (BE) 210, an HfO₂ switching layer 212, a titanium (Ti) oxygen scavenging layer 214, and a TiN top electrode (TE) 216.

The TiN BE 210 can be integrated on top of a tungsten (W) M1 layer 202. In some embodiments, the HfO₂ switching layer 212 can have a thickness of 5.8 nm and can be deposited via an atomic layer deposition (ALD) technique, and can be covered by the Ti OSL 214, which can, in some embodiments, have a thickness of 6 nm. In some embodiments, the TiN film can be deposited with a thickness of 40 nm as the TE. In embodiments, both TE and BE can be deposited through the physical vapor deposition (PVD) technique. Lastly, the device can be lithographically patterned through a custom reactive ion etch (RIE) process.

In some embodiments, the RRAM can be made in a 1T1R configuration as shown in the inset of FIG. 3, where each RRAM can be connected to a n-channel field effect transistor (NFET) that serves as the on-chip current controller to limit the compliance current. Each individual 1T1R cell and a crossbar array can be made with bottom metal layers (metal-1 and metal-2). Cross-wires (connections between the crossbar and bonding pads for measurement) can be made with top metal layers (metal-5 and metal-6). The crossbar is covered by the top metal (parallel vertical lines shown in FIG. 3, inset).

A device characterization can be performed directly on wafer pieces using a semi-automatic probe station. The probe station can be connected to an E5250A switch matrix and a B1500 semiconductor device analyzer. The equipped high resolution source measure unit (SMU) and waveform generator/fast measurement unit (WGFMU) can then be used to enable simultaneous high-speed measurements, where fully-automatic operating software can be created from, for example, in-house Python code.

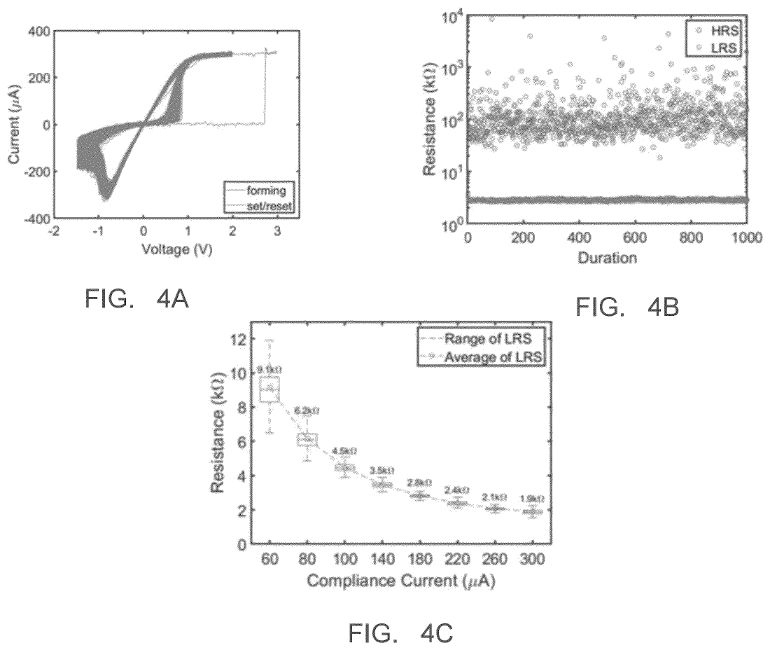

Referring to FIG. 4A, FIG. 4B, and FIG. 4C, device characteristics of HfO₂ RRAM in 1T1R configuration are shown. More specifically, FIG. 4A shows a switching behavior plotted in the form of an iv curve, FIG. 4B shows device endurance in the form of resistance states for 1000 switching cycles, and FIG. 4C shows memory windows of LRS for 8000+ switching cycles.

In this operational exemplary embodiment, a controlled gate voltage was applied to an NFET fixed at 1.5 V. To initiate the conductivity of CF, RRAM was first formed with a compliance current of 150 μA with a forming voltage at 3 V. Afterward, with a driving voltage of 2 V, a forward-biased current switched the RRAM to its LRS. An ohmic behavior was observed until a negative voltage was applied (i.e., −1.7 V), which can induce a reverse-biased current to switch the RRAM to its HRS. For 1000+testing cycles, embodiments of the RRAM exhibited a pinched-hysteresis in the iv curve, reliably switching the device from one state to another. This curve is shown in FIG. 4A. On/Off Ratio: Embodiments of the RRAM offered an on/off ratio of 25, where the average LRS and HRS were reported as 4 kΩ and 100 kΩ, respectively, as shown in FIG. 4B. Such a large on/off ratio can distinguish the binary “1” (read as LRS) and “0” (read as HRS) in a differential read-out manner. Multi-bit Computation: Unlike static/dynamic RAM and flash memories that are binary in nature, individual RRAM can provide the multi-bit computation capability by yielding multiple resistance values within the LRS regime.

FIG. 4C shows various resistance values would be obtained by controlling the compliance current written into the device. For instance, with a compliance current varied between 60 μA and 300 μA, the LRS changed from 9.1 kΩ to 1.9 kΩ accordingly. This range of LRS could potentially distinguish individual RRAM into 4-8 states, offering 2-3 bits precision for analogue CIM.

TABLE 1
Retention of two selected devices drawn
from a crossbar array over a month period

| | Initial | +1 wk | +2 wks | +3 wks | +4 wks |
|---|---|---|---|---|---|
| Sample 1 | 4.0 kΩ | 4.5 kΩ | 4.0 kΩ | 3.0 kΩ | 3.7 kΩ |
| Sample 2 | 3.5 kΩ | 2.3 kΩ | 2.3 kΩ | 2.3 kΩ | 2.3 kΩ |

Unquestionably, the stability and reliability of memory cells over time is of high importance for mission critical applications. Such a property is known as retention. Table 1 summarizes the non-volatility of two randomly selected samples—initiated to LRS—over a month period. While both samples were capable to retain their LRS, their actual resistance value drifted by 7.5%-to-34.3%. Potential mechanisms that can affect the retention behaviors include initial relaxation, temperature variation, and read disturb. In short, embodiments of the RRAM described herein could precisely retain the binary information for digital computations, and yet, more optimizations are still needed to fully realize analogue CIM with multi-bit computations, for instance, (1) designing a more precise driver to control the filament formation and reduce thermal damage, (2) implementing error correction/calibration techniques to prevent over-setting/resetting and enhance the retention of individual cell, and (3) leveraging verify algorithm to enhance linearity for multi-bit storage and improve uniformity.

Given the success of RRAM when retaining binary information, such devices can be applied for digital computations to reduce the hardware resources when compared with conventional approaches. For example, a hardware prototype of a 1T1R crossbar array can be used for computing Boolean arithmetic by interacting with resistance state variables and the path of current flow within the crossbar array.

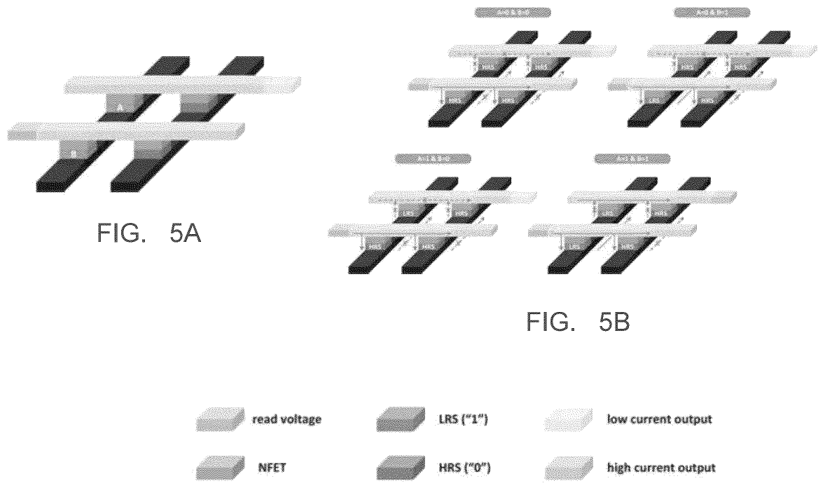

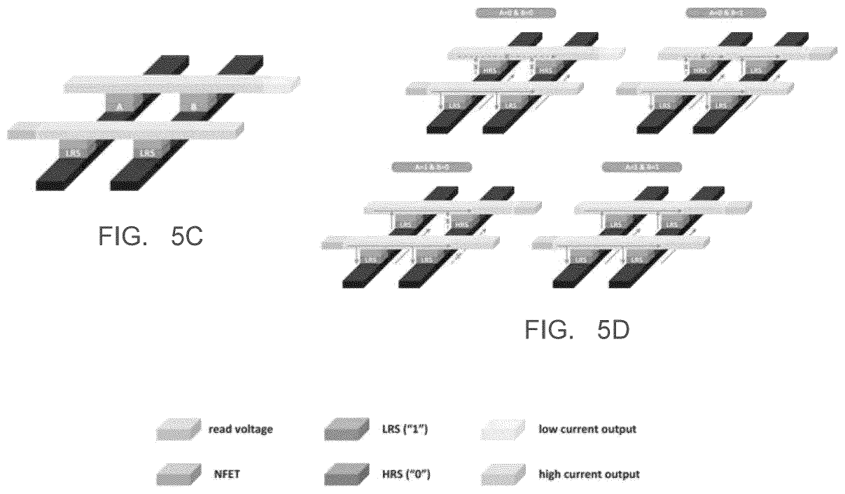

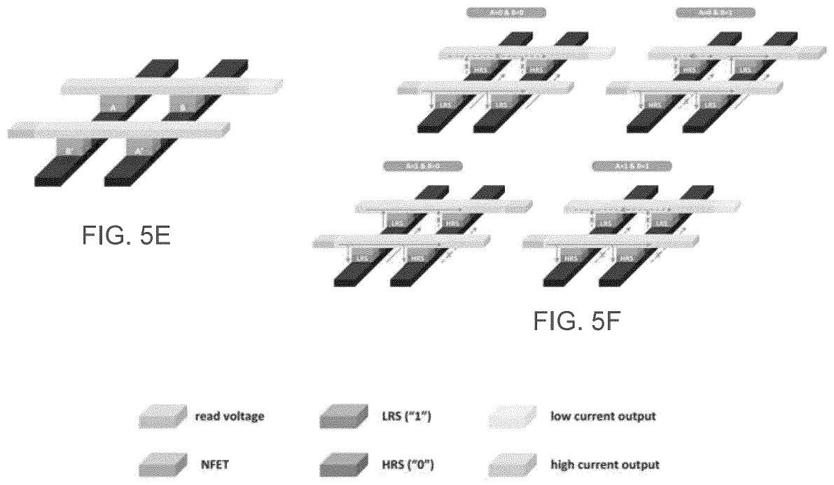

FIG. 5A and FIG. 5B show a cell configuration and operating principle for an AND gate. FIG. 5C and FIG. 5D show the cell configuration and operating principle for an OR gate. FIG. 5E and FIG. 5F show the cell configuration and operating principle for an XOR gate.

In the configurations shown in FIGS. 5A-5F, binary digits in the Boolean formula can be represented by the resistance state of RRAM. With a read voltage (i.e., 0.2 V) applied to one of the word-lines (WL) while all bit-lines (BL) were floating, a current flow was established when the RRAM was set to be LRS, otherwise, the current flow was negligible. The output was then recorded in accordingly to the current level sampled at the other WL. A current threshold (i.e., Iₜₕ=15 μA) was defined to differentiate the binary output, for instance, binary “1” was output if lₒᵤₜ>Iₜₕ or “0” otherwise. As mentioned, an example of two-input XOR is depicted in FIG. 5F. When A=B, RRAMs located at the top WL (or bottom WL) were set to be HRS, limiting the current flow through these devices, thereby the accumulated current remained low at the output. By contrast, when A≠B, one of the BLs established a higher current flow, thereby the accumulated current increased at the output. This operating manner would also be applied for computing AND and OR, as summarized in Table 2. In general, the size of crossbar array scales up linearly as the number of input digits increases. For instance, it took a 2×2 array to compute a 2-input Boolean formula but a 3×3 array for 3-input computation. Compared to conventional approaches used in modern digital computers, a flow-based operation performs Boolean arithmetic directly in memory sub-array and needs no power overhead from data movement and external circuitry, such as shift register and sensing amplifiers, making such an implementation more suitable for power- and area-limited edge devices.

TABLE 2
Experimental results of three different flow-based
Boolean arithmetic measured in terms of current

| | | AND | OR | XOR |
|---|---|---|---|---|
| A | B | (μA) | (μA) | (μA) |
| HRS | HRS | 1.8 | 2.8 | 2.6 |
| HRS | LRS | 2.1 | 36.0 | 27.0 |
| LRS | HRS | 5.6 | 35.0 | 26.0 |
| LRS | LRS | 26.0 | 52.0 | 5.3 |

While MAC takes part in most AI/ML algorithms, CIM in the analogue space has emerged as a promising solution due to the inherent parallelism of its crossbar nature. In embodiments described herein, the 1T1R crossbar array can be utilized to realize MAC acceleration that is applicable for general classification problems.

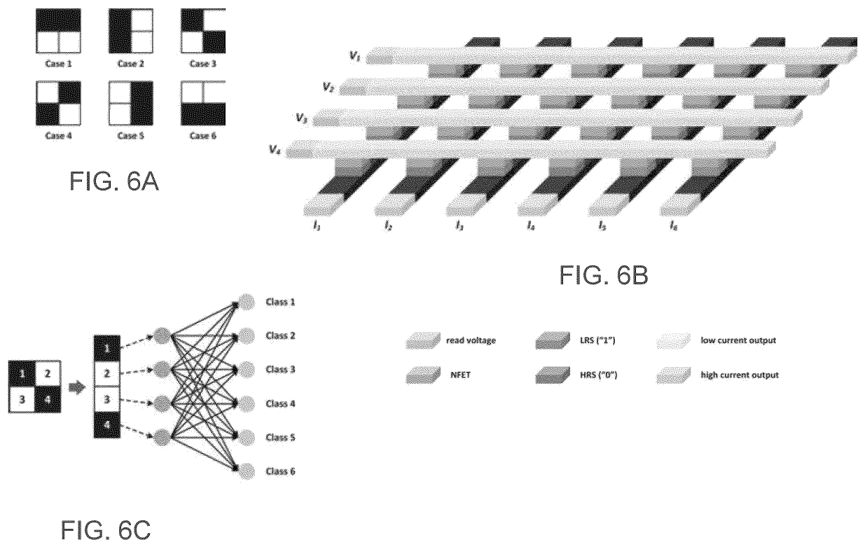

In embodiments, an SLP classifier can be built on a 4×6 crossbar array as shown in FIG. 6B. As shown in FIG. 6A, a simple test set made of 2×2 pixel blocks—in six different combinations of pixels—can be adopted for positioning of dark pixels. By mapping input tensors as voltages loaded in parallel on each WL and weight values as the conductance of RRAMs, MAC is obtained in an analog fashion by sampling the accumulated current on each BL, such that Iⱼ=ΣVᵢ·Gᵢⱼ, where Vᵢ is the input voltage at i-th WL and Gᵢⱼ=1/Rᵢⱼ is the conductance of RRAM stacked between i-th WL andj-th BL.

First, the column-wise resistance of each RRAM can be set according to the corresponding pixel information of each case, for instance, HRS for light pixels and LRS for dark pixels, as depicted in FIG. 6B. Each pixel block can then be reshaped into a one-dimensional column vector and read into the crossbar concurrently, where light pixels can be read as 0 V and dark pixels can be read as 0.2 V. In this way, different cases can be distinguished by the accumulated current on each BL, and the positioning can be conducted by the winner-take-all (WTA) approach, as summarized in Table 3.

TABLE 3
Experimental results of dark pixel positioning using
MAC and WTA approaches.

| | I₁ | I₂ | I₃ | I₄ | I₅ | I₆ |
|---|---|---|---|---|---|---|
| | (μA) | (μA) | (μA) | (μA) | (μA) | (μA) |
| Case 1 | 143 | 55 | 54 | 54 | 51 | 4.4 |
| Case 2 | 54 | 110 | 51 | 58 | 8 | 52 |
| Case 3 | 53 | 68 | 140 | 5 | 53 | 45 |
| Case 4 | 60 | 52 | 4.1 | 142 | 58 | 58 |
| Case 5 | 54 | 6.1 | 58 | 52 | 108 | 46 |
| Case 6 | 38 | 54 | 47 | 49 | 60 | 145 |

Such a CIM approach can enable classification problems through MAC operations to be performed in place in the memory sub-array, offloading costs in latency and energy as well as hardware resources associated with data movement.

The crossbar arrays with 1T1R configuration indeed offer exceptional improvements in accelerating neural-inspired computations. However, the resultant classification accuracy is degraded when handling more sophisticated AI/ML related workloads due to the fact that the individual 1T1R cell has no capability to represent negative weight values. Existing solutions leverage two independent crossbar arrays, where one represents the positive and the other represents the negative. Alongside the current sensing amplifiers, a subtraction operation is made to emulate the calculation of negative weight values, and yet, leading to additional hardware resources such as larger silicon area, higher power consumption, and increased circuit/system complexity. In fact, the data processing challenge threatens to completely undercut the transformative low cost, size, weight, and power (C-SWaP) nature of RRAM. To this end, innovative circuit implementations for RRAM that reconfigure the data processing flow may be required.

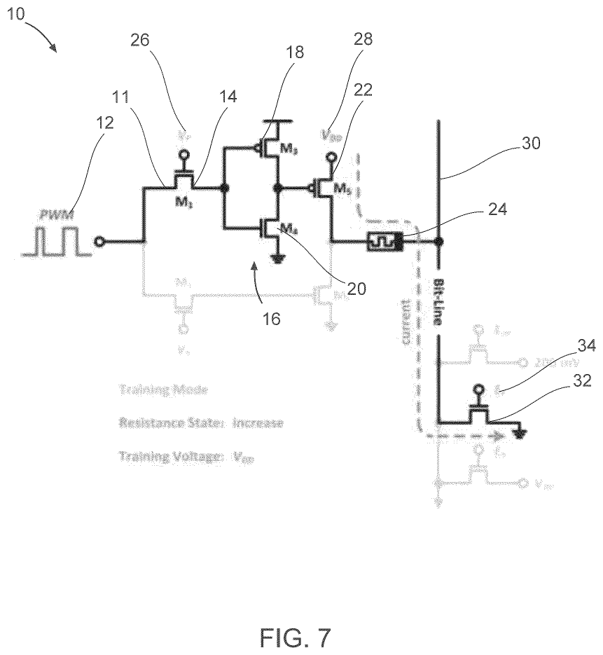

FIG. 7 shows a training mode cell configuration for a 6T1R cell 10 and operating principle of the 6T1R under a training mode to increase RRAM's resistance (i.e., positive weight). The 6T1R cell 10 is coupled to a signal source (in this case a pulse width modulator (PWM) 12) and includes a first control channel 11, which may be a positive weight conduction loop that activates to control an increase in the resistance of the RRAM 24. The first control channel 11 can include a first transistor (M₁) 14, a logic inverter 16 including a third transistor (M₃) 18 and a fourth transistor (M₄) 20, a fifth transistor (M₅) 22, and the RRAM 24. In a resistance increase training mode, the cell can receive control and source signals from various sources including a positive resistance control signal Vₚ 26 and a source signal voltage V_{DD} 28 (training signal). After the RRAM 24, V_{DD} 28 may be grounded through a bit line 30 through a second bit line transistor 32 based on a positive bit line control signal Eₚ 34. With the cell 10 in a training mode, current may flow from the source signal voltage V_{DD} 28 through the RRAM 24 to increase the RRAM's resistance.

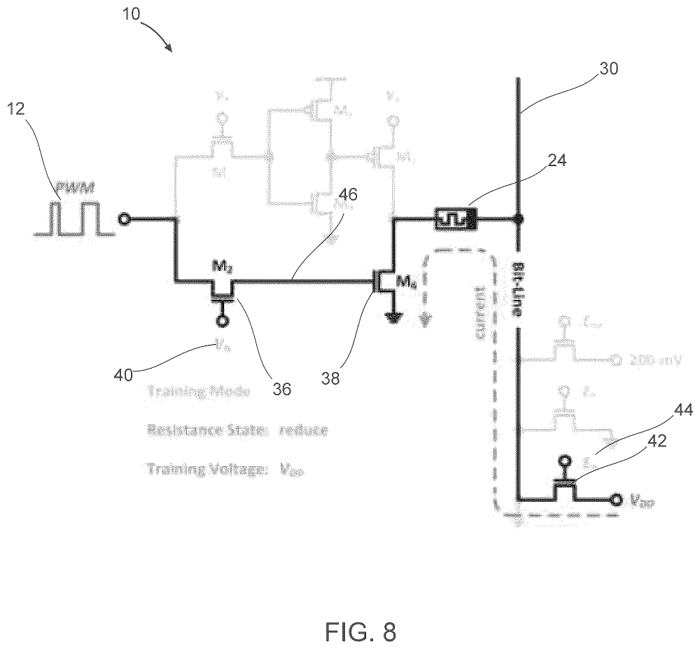

FIG. 8 shows a cell configuration and operating principle of the 6T1R under the training mode to reduce RRAM's resistance. In the training mode to reduce the resistance of the RRAM 24, the training signal V_{DD} may be provided via a transistor 42 controlled by a signal E_{N} 44 and the bit line 30. The signal may pass through the RRAM 24 and then through a portion of the second control channel 46 of the 6T1R cell 10 that can include a second transistor (M₂) 36 controlled by a V_{N} 40 and a sixth transistor (M₆) 38. The second control channel 46 can be a negative weight conduction loop that activates to reduce a resistance of the RRAM 24. With the second control channel 46 active, a signal may flow through the RRAM 24 then through the sixth transistor 38 to ground. The path of current through the RRAM 24 may reduce the resistance according to the principles shown and described herein. In the specific embodiment shown, M₁, M₄, M₂, and M₆ can be NFET transistors, while M₃ and M₅ can be PFET transistors, but other embodiments are possible.

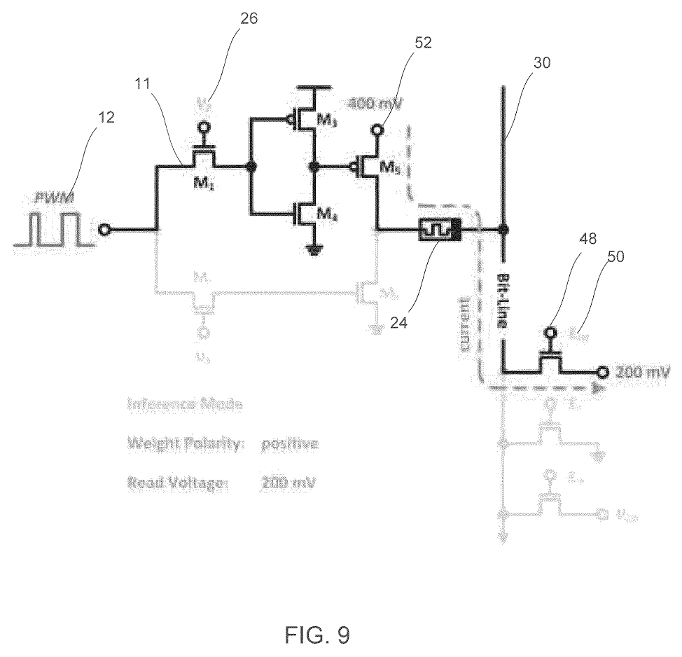

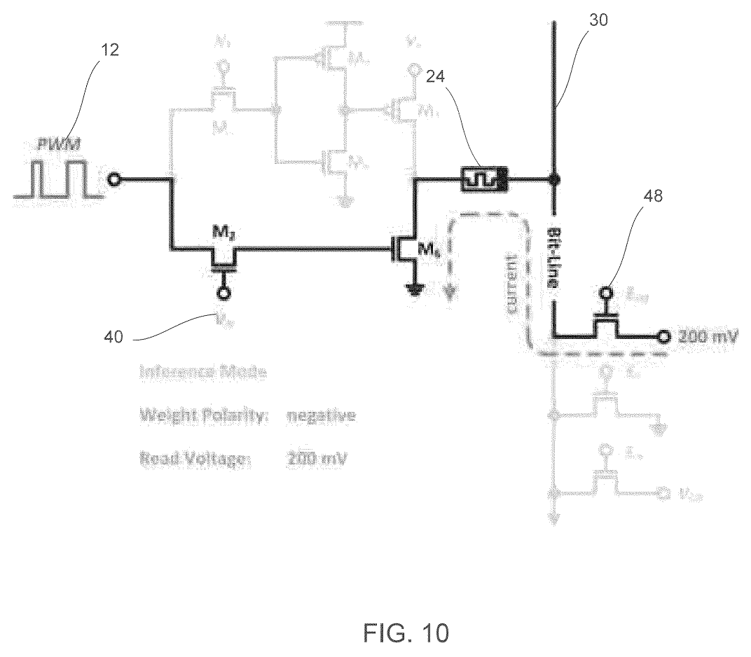

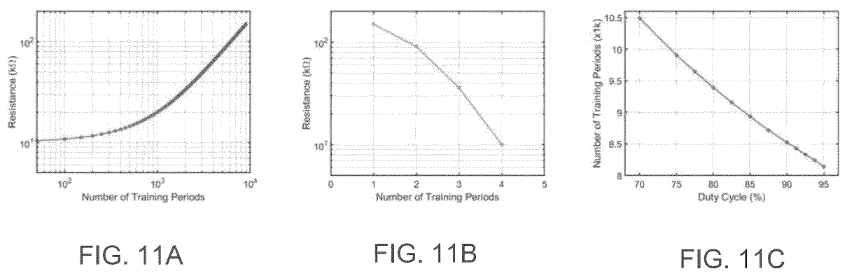

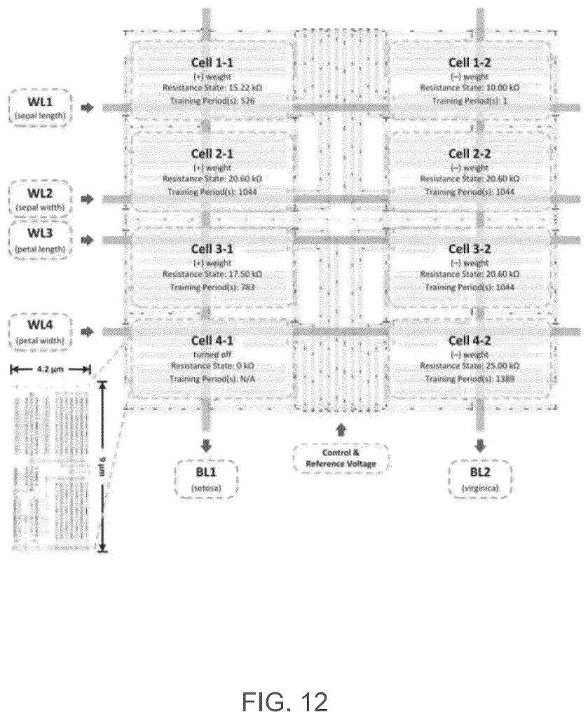

FIG. 9 shows a cell configuration and operating principle of the 6T1R under the inference mode with positive weight values and FIG. 10 shows a cell configuration and operating principle of the 6T1R under the inference mode with negative weight values.

In this effort, the memristive circuitry can be redesigned by introducing a bidirectional current control mechanism alongside the temporal switching capability. Here, the basic building blocks of a CIM accelerator are made of 6T1R cell. Such an enhanced circuit design demonstrates several advantages in addition to the multi-bit computation: (1) programming individual 6T1R cell to realize either positive or negative weight values by controlling the direction of current written/read into the device, (2) supporting computations with both positive and negative input tensors, and (3) enabling in-situ training with no power/area overhead from peripherals.

Beyond that, embodiments of the current circuitry can leverage the temporal-encoded (also known as pulse-width modulated, PWM) pulses as computing variables for energy efficiency, where raw sensory data is encoded by varying the duty cycle of constant-amplitude pulses at a fixed clock frequency.

The cell configuration and operating principle of current 6T1R embodiments are illustrated in FIG. 7, FIG. 8, FIG. 9, and FIG. 10. In the training mode, V_{H} can be fixed at VDD (e.g., 1.2 V) while the voltage at BL can vary according to the desired training purposes. For instance, to increase the RRAM's resistance, control signals of V_{P} and E_{P} can be enabled while V_{N} and E_{N} can be grounded, as depicted in FIG. 7. In this way, M₁ can forward the PWM pulses to trigger the logic inverter (made of M3 and M4) while M2 is cut off. As such, M5 will be active and, simultaneously, the BL is pinned at 0 V, allowing high-amplitude voltage pulses to be applied across the RRAM with a forward-biased current causing the transition to HRS.

By contrast, to reduce RRAM's resistance, the aforementioned control signals can be reversed, as depicted in FIG. 8. As shown, the PWM pulses are passed by M2 and cut off by M1. The bit line 30 can be pinned at V_{DD}. With a similar operation, a reverse-biased current can then be observed through the RRAM causing a transition to the LRS. In embodiments, other cells that may not be involved in training, both V_{P} and V_{N} can be grounded for energy efficiency and to eliminate sneak paths.

In the inference mode, such as shown in FIGS. 9 and 10, a V_{H} 52 can be fixed at, for example, 400 mV while the voltage at BL can be pinned at 200 mV by enabling E_{inf} 50 through a transistor 48. To read out a positive weight value, control signal of V_{P} can be enabled while V_{N} can be grounded, as shown in FIG. 9. Similar as in the training mode, with M5 being triggered, the read voltage (i.e., 400 mV-200 mV) can produce a pulse of forward-biased current flow through the RRAM 24 without overwriting its resistance value. Conversely, to read out a negative weight value, control signal of V_{P} and V_{N} can then be reversed accordingly, as shown in FIG. 10. With M6 being triggered with M₁ being cut off, the read voltage (i.e., 200 mV-0 V) produced a pulse of reverse-biased current flow through the RRAM. In short, a forward-biased current through the RRAM was read as positive weight value while a reverse-biased current was read as negative.

Eventually, these resulting current pulses from each individual RRAM were then accumulated (while negative current pulses were removed) with others along the processing BL. By doing so, individual 6T1R, rather than a pair of 1T1Rs with current sensing amplifier, would realize either positive or negative weight values, removing the necessity of peripherals for signal subtraction and significantly improving the energy and area efficiency. More importantly, such operation manners would also be applied to compute negative input tensors, in a way to swap the polarity of weight values (i.e., the current direction) in the entire WL.

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A memristive circuit comprising:
a signal source;
a bit line; and
a six-transistor, one-resistive random-access memory (6T1R) cell comprising:
a resistive random-access memory (RRAM) element having a first terminal and a second terminal, the second terminal being electrically coupled to the bit line;
a positive-weight conduction loop comprising:
a first transistor (M₁) having a gate configured to receive a positive-state gate voltage (Vₚ), a source coupled to the signal source, and a drain configured to control a state of a logic inverter, wherein the first transistor is configured to selectively pass the signal source to the logic inverter;
the logic inverter, comprising a third transistor (M₃) and a fourth transistor (M₄), each having gates coupled to the drain of M₁, the logic inverter having an output; and
a fifth transistor (M₅) having a gate coupled to the output of the logic inverter, a source coupled to a training supply voltage (VDD), and a drain coupled to the first terminal of the RRAM element; and
a negative-weight conduction loop comprising:
a second transistor (M₂) having a source coupled to the signal source and a gate configured to receive a negative-state gate voltage (Vₙ); and
a sixth transistor (M₆) having a gate coupled to a draing of the second transistor, a drain coupled to the first terminal of the RRAM element, and a source coupled to ground; and wherein
the RRAM element is configured to store a plurality of resistance states corresponding to magnitudes of synaptic weights, a sign and magnitude of the synaptic weight being determined by a direction and a magnitude of current conducted through the RRAM element via one of the positive-weight conduction loop and the negative-weight conduction loop; and
during a read operation, the resistance state of the RRAM element modulates a current on the bit line, a magnitude of the current thereby representing the magnitude of the synaptic weight.

2. The memristive circuit of claim 1, wherein the RRAM element comprises a metal-oxide material.

3. The memristive circuit of claim 2, wherein the RRAM element comprises HfO₂.

4. The memristive circuit of claim 1, wherein the logic inverter is a complementary metal-oxide-semiconductor (CMOS) inverter, the third transistor (M₃) being a p-type transistor and the fourth transistor (M₄) being an n-type transistor.

5. The memristive circuit of claim 1, wherein current conduction through the positive-weight conduction loop performs a Long-Term Potentiation (LTP) operation on the synaptic weight, and wherein current conduction through the negative-weight conduction loop performs a Long-Term Depression (LTD) operation on the synaptic weight.

6. The memristive circuit of claim 1, wherein the signal source provides a voltage pulse corresponding to an activation of a pre-synaptic neuron.

7. The memristive circuit of claim 1, wherein the positive-state gate voltage (Vₚ) and the negative-state gate voltage (Vₙ) are configured as non-overlapping voltage pulses, thereby ensuring that the positive-weight and negative-weight conduction loops are not active simultaneously.

8. A memristive array comprising a plurality of the memristive circuits of claim 1, and further comprising a word line, wherein for each memristive circuit in a row of the array, the source of the first transistor and the source of the second transistor are electrically coupled to the word line.

9. An array of memristive circuit cells comprising:
a word line;
a bit line;
a plurality of a six-transistor, one-resistive random-access memory (6T1R) cells coupled between the word line and bit line, each cell comprising:
a resistive random-access memory (RRAM) element having a first terminal and a second terminal, the second terminal being electrically coupled to the bit line;
a positive-weight conduction loop comprising:
a first transistor (M₁) having a gate configured to receive a positive-state gate voltage (Vₚ), a source coupled to the word line, and a drain configured to control a state of a logic inverter, wherein the first transistor is configured to selectively pass the signal source to the logic inverter;
the logic inverter, comprising a third transistor (M₃) and a fourth transistor (M₄), each having gates coupled to the drain of M₁, the logic inverter having an output; and
a fifth transistor (M₅) having a gate coupled to the output of the logic inverter, a source coupled to a training supply voltage (VDD), and a drain coupled to the first terminal of the RRAM element; and
a negative-weight conduction loop comprising:
a second transistor (M₂) having a source coupled to the word line and a gate configured to receive a negative-state gate voltage (Vₙ); and
a sixth transistor (M₆) having a gate coupled to a drain of the second transistor, a drain coupled to the first terminal of the RRAM element, and a source coupled to ground; and wherein
each RRAM element is configured to store a plurality of resistance states corresponding to magnitudes of synaptic weights, a sign and magnitude of the synaptic weight being determined by a direction and a magnitude of current conducted through the RRAM element via one of the positive-weight conduction loop and the negative-weight conduction loop,
asserting a voltage on the word line selects each cell coupled thereto by providing an input voltage to the source of the first transistor (M₁) and the source of the second transistor (M₂), thereby enabling one of the positive-weight conduction loop and the negative-weight conduction loop to modify the resistance state of the RRAM element, and
during a read operation, the resistance state of the RRAM element modulates a current on the bit line, a magnitude of the current thereby representing the magnitude of the synaptic weight.

10. The array of memristive circuit cells of claim 9, wherein the RRAM element comprises a metal-oxide material.

11. The array of memristive circuit cells of claim 10, wherein the RRAM element comprises HfO₂.

12. The array of memristive circuit cells of claim 9, wherein the logic inverter is a complementary metal-oxide-semiconductor (CMOS) inverter, the third transistor (M₃) being a p-type transistor and the fourth transistor (M₄) being an n-type transistor.

13. The array of memristive circuit cells of claim 9, wherein current conduction through the positive-weight conduction loop performs a Long-Term Potentiation (LTP) operation on the synaptic weight, and wherein current conduction through the negative-weight conduction loop performs a Long-Term Depression (LTD) operation on the synaptic weight.

14. The array of memristive circuit cells of claim 9, wherein the signal source provides a voltage pulse corresponding to an activation of a pre-synaptic neuron.

15. The array of memristive circuit cells of claim 9, wherein the positive-state gate voltage (Vₚ) and the negative-state gate voltage (Vₙ) are configured as non-overlapping voltage pulses, thereby ensuring that the positive-weight and negative-weight conduction loops are not active simultaneously.
